(19) United States
(12) Patent Application Publication
(10) Pub. No.: US 2014/0360763 A1
(43) Pub. Date: Dec. 11, 2014

(54) CONDUCTIVE PASTE AND METHOD FOR PRODUCING CONDUCTIVE PATTERN

(71) Applicant: Toray Industries, Inc., Tokyo (JP)

(72) Inventors: Tsukuru Mizuguchi, Otsu (JP); Kazutaka Kusano, Otsu (JP)

(73) Assignee: Toray Industries, Inc., Tokyo (JP)

(21) Appl. No.: 14/372,566

(22) PCT Filed: Jan. 10, 2013
(86) PCT No.: PCT/JP2013/050250

§ 371 Date: Jul. 16, 2014

(30) Foreign Application Priority Data
Jan. 19, 2012 (JP) 2012-008657
Oct. 25, 2012 (JP) 2012-235385

(51) Int. Cl. H01B 1/22; H05K 1/09; G03F 7/20; H05K 1/02

(52) U.S. Cl. CPC H01B 1/22; H05K 1/0274; H05K 1/092; G03F 7/20; H05K 2201/0326
USPC 174/257; 252/514; 430/325

(57) ABSTRACT

A conductive paste includes: composite particles (A) formed by coating a surface of a core material composed of an inorganic material with an antimony-containing compound; a compound (B) having an acid value of 30 to 250 mg KOH/g; and a conductive filler (C).

### TECHNICAL FIELD

This disclosure relates to conductive paste for forming a conductive pattern.

### BACKGROUND

In recent years, conductive pastes in which a conductive filler such as Ag is dispersed in an organic component containing a resin have been used for peripheral wiring of transparent touch panels, wiring for circuit boards and membrane switches (see, for example, Japanese Patent Laid-open Publication No. 2007-207567 and Japanese Patent Laid-open Publication No. 2011-246498). However, such conductive pastes have the problem that narrow-pitch wiring cannot be formed because wiring is formed by screen printing and, therefore, bleeding, plate clogging or the like easily occurs. Thus, a technique has been proposed in which photosensitivity is imparted to an organic component containing a resin, and a paste is applied to a substrate, and then subjected to exposure and development steps so that narrow-pitch wiring can be formed (see, for example, International Publication No. WO 04/061006 and Japanese Patent Laid-open Publication No. 2003-162921). However, when these photosensitive pastes are used for peripheral wiring of touch panels, there is the problem that connection reliability with indium tin oxide (hereinafter, referred to as ITO) is not obtained. As a method of enhancing connection reliability with ITO in a conductive paste, a technique has been proposed in which an antimony-doped tin oxide fine powder is added in a conductive paste (see, for example, Japanese Patent Laid-open Publication No. 2009-295325).

However, there is the problem that an alkali-soluble organic component given photosensitivity generally has a high acid value and, therefore, even when an antimony-doped tin oxide powder is added, tin oxide is corroded so that connection reliability with ITO is not obtained, and adhesion is deteriorated or residues are generated.

tin oxide powder is added, tin oxide is corroded so that connection reliability with ITO is not obtained, and adhesion is deteriorated or residues are generated.

It could therefore be helpful to provide a conductive paste suitable for obtaining a conductive pattern, which has high connection reliability with ITO despite containing a compound having a high acid value and which is capable of fine patterning, and a method of producing a conductive pattern.

### SUMMARY

We thus provide a conductive paste including: composite particles (A) formed by coating the surface of a core material composed of an inorganic material with an antimony-containing compound; a compound (B) having an acid value of 30 to 250 mg KOH/g; and a conductive filler (C), and a method for producing a conductive pattern, wherein the conductive paste is applied onto a substrate, dried, exposed, developed, and then cured at a temperature of 100° C. or more and 300° C. or less.

Good connection reliability with ITO can thus be obtained despite the conductive paste containing a compound having a high acid value. According to the preferred configuration, narrow-pitch wiring can be formed not only on a rigid substrate by also on a flexible substrate.

### BRIEF DESCRIPTION OF THE DRAWINGS

FIG. 1 is a schematic view showing a light transmission pattern of a photomask used in evaluation of the specific resistivity in examples.

FIG. 2 schematically shows a sample used in a flexibility test in examples.

FIG. 3 is a schematic view showing a light transmission pattern of a photomask used in evaluation of connection reliability with ITO in examples.

### DESCRIPTION OF REFERENCE SIGNS

A Light transmission part
B, C Sample short side
D Conductive pattern
E PET film

### DETAILED DESCRIPTION

Our conductive paste includes: composite particles (A) formed by coating the surface of a core material composed of an inorganic material with an antimony-containing compound; a compound (B) having an acid value of 30 to 250 mg KOH/g; and a conductive filler (C).

The conductive paste is applied onto a substrate, dried to remove a solvent as necessary, and then subjected to exposure, development and a curing step at 100° C. or more and 300° C. or less, whereby a desired conductive pattern can be obtained on the substrate. The conductive pattern obtained using the paste is a composite of an organic component and an inorganic component, and conductive fillers come into contact with one another due to setting shrinkage during curing to exhibit conductivity.

The composite particle (A) contained in the conductive paste and formed by coating the surface of a core material composed of an inorganic material with an antimony-containing compound refers to a particle in which the surface of a core material composed of an inorganic material is coated with an antimony-containing compound in a thickness of 1 nm or more. Examples of the antimony-containing compound include antimony sulfide, antimony trioxide, antimony pentaoxide, lead antimonate, indium antimonide and antimony-doped tin oxide. Examples of the inorganic material that forms the core material include titanium oxide, barium sulfate, aluminum oxide, silicon dioxide, zinc oxide, magnesium oxide, calcium oxide, iron oxide, nickel oxide, ruthenium oxide, indium oxide, copper oxide, carbon, silver (Ag), gold (Au), copper (Cu), platinum (Pt), lead (Pb), tin (Sn), nickel (Ni), aluminum (Al), tungsten (W), molybdenum (Mo), chromium (Cr) and titanium (Ti).

The volume average particle size of the composite particles (A) formed by coating the surface of a core material composed of an inorganic material with an antimony-containing compound is preferably 0.03 to 10 μm, more preferably 0.1 to 6 μm. A volume average particle size of 0.03 μm or more is preferred because dispersibility and dispersion stability are high so that generation of aggregates can be suppressed and, therefore, a sufficient effect of connection reliability with ITO is obtained with respect to an added amount. A volume average particle size of 6 μm or less is preferred because surface smoothness, pattern accuracy and dimensional accuracy of a circuit pattern after printing are improved. The volume average particle size can be determined by the Coulter counter method, the photon correlation method, the laser diffraction method and so on.

When the aspect ratio of the composite particles (A) formed by coating the surface of a core material composed of an inorganic material with an antimony-containing compound is 1.5 to 50, the tap density decreases so that connection reliability with ITO can be enhanced with a low added amount, but the aspect ratio is more preferably 10 to 50.

The added amount of the composite particles (A) formed by coating the surface of a core material composed of an inorganic material with an antimony-containing compound is preferably 0.1 to 20% by weight, more preferably 1 to 10% by weight based on the total solid content in the conductive paste. It is preferred that the added amount of the composite particles (A) is 0.1% by weight or more because connection reliability with ITO is particularly enhanced. It is preferred that the added amount of the composite particles (A) is 20% by weight or less because influences on the conductivity of the conductive pattern can be reduced. The total solid content is a content after removing a solvent from the conductive paste.

The compound (B) contained in the conductive paste and having an acid value of 30 to 250 mg KOH/g refers to a compound having at least one carboxyl group in the molecule, and one or more kinds thereof can be used.

Specific examples of the compound (B) include acryl-based copolymers, polyester-based resins and polyurethane-based resins.

The acryl-based copolymer is a copolymer containing at least an acryl-based monomer as a copolymerization component, and specific examples of the preferred acryl-based monomer include acryl-based monomers such as methyl acrylate, acrylic acid, 2-ethylhexyl acrylate, ethyl methacrylate, n-butyl acrylate, i-butyl acrylate, i-propane acrylate, glycidyl acrylate, N-methoxymethylacrylamide, N-ethoxymethylacrylamide, N-n-butoxymethylacrylamide, N-isobutoxymethylacrylamide, butoxytriethylene glycol acrylate, dicyclopentanyl acrylate, dicyclopentenyl acrylate, 2-hydroxyethyl acrylate, isobonyl acrylate, 2-hydroxypropyl acrylate, isodecyl acrylate, isooctyl acrylate, lauryl acrylate, 2-methoxyethyl acrylate, methoxyethylene glycol acrylate, methoxydiethylene glycol acrylate, octafluoropentyl acrylate, phenoxyethyl acrylate, stearyl acrylate, trifluoroethyl acrylate, acrylamide, aminoethyl acrylate, phenyl acrylate, phenoxyethyl acrylate, 1-naphthyl acrylate, 2-naphthyl acrylate, thiophenol acrylate and benzylmercaptan acrylate, and those with acrylate of the above-mentioned monomers replaced by methacrylate, styrenes such as styrene, p-methylstyrene, o-methylstyrene, m-methylstyrene, α-methylstyrene, chloromethylstyrene and hydroxymethylstyrene, γ-methacryloxypropyl trimethoxysilane, 1-vinyl-2-pyrrolidone, allylated cyclohexyl diacrylate, 1,4-butanediol diacrylate, 1,3-butyrene glycol diacrylate, ethylene glycol diacrylate, diethylene glycol diacrylate, triethylene glycol diacrylate, polyethylene glycol diacrylate, dipentaerythritol hexaacrylate, dipentaerythritol monohydroxypentaacrylate, ditrimethylolpropane tetraacrylate, glycerol diacrylate, methoxylated cyclohexyl diacrylate, neopentyl glycol diacrylate, propylene glycol diacrylate, polypropylene glycol diacrylate, triglycerol diacrylate, trimethylolpropane triacrylate, bisphenol A diacrylate, bisphenol F diacrylate, diacrylates of bisphenol A-ethylene oxide adducts, diacrylates of bisphenol F-ethylene oxide adducts, diacrylates of bisphenol A-propylene oxide adducts, acrylic acid adducts of ethylene glycol diglycidyl ether, acrylic acid adducts of diethylene glycol diglycidyl ether, acrylic acid adducts of neopentyl glycol diglycidyl ether, acrylic acid adducts of glycerin diglycidyl ether, and epoxy acrylate monomers such as acrylic acid adducts of bisphenol A diglycidyl ether, acrylic acid adducts of bisphenol F and acrylic acid adducts of cresol novolak, or compounds with acryl groups of the above-mentioned compounds partially or wholly replaced by methacryl groups although all compounds having a carbon-carbon double bond can be used.

Alkali solubility can be imparted to an acryl-based copolymer by using as a monomer an unsaturated acid such as an unsaturated carboxylic acid. Specific examples of the unsaturated acid include acrylic acid, methacrylic acid, itaconic acid, crotonic acid, maleic acid, fumaric acid and vinyl acetate or acid anhydrides thereof. By adding the above-mentioned unsaturated acid to the molecular chain, the acid value of the polymer can be adjusted.

An alkali-soluble polymer having a reactive unsaturated double bond on the side chain can be prepared, the alkali-soluble polymer being obtained by reacting a part of an unsaturated acid in an acryl polymer obtained using as a monomer an unsaturated acid such as the above-mentioned unsaturated carboxylic acid with a compound having both a group reactive with an unsaturated acid and a group having an unsaturated double bond, such as glycidyl(meth)acrylate.

The acid value of the compound (B) contained in the conductive paste should be 30 to 250 mg KOH/g from the viewpoint of alkali solubility, and when the acid value is 30 mg KOH/g or more, solubility of a soluble part in a developer is not reduced, and when the acid value is 250 mg KOH/g or less, the development allowance range can be broadened. The acid value is determined in accordance with JIS-K0070 (1992).

The glass transition temperature of the compound (B) contained in the conductive paste is preferably −10 to 60° C., more preferably 10 to 50° C. When Tg is −10° C. or higher, tackiness of the dry film can be suppressed, and when Tg is 10° C. or higher, shape stability particularly to a change in temperature is enhanced. When Tg is 60° C. or lower, flexibility is

[symbol]

Although the glass transition temperature of the compound (B) contained in the conductive paste can be determined by differential scanning calorimetry (DSC), the glass transition temperature of the compound (B) can be calculated from the following equation (1) using copolymerization ratios of monomers as copolymerization components and glass transition temperatures of homopolymers of the monomers. The calculated value is used when the glass transition temperature can be calculated, and the glass transition temperature is determined from the result of DSC measurement when a monomer for which a homopolymer has an unknown glass transition temperature.

$$\frac{1}{Tg} = \frac{W 1}{T 1} + \frac{W 2}{T 2} + \frac{W 3}{T 3} + … \qquad ( 1 )$$

Wherein Tg is a glass transition temperature (unit: K) of a polymer, T1, T2, T3 . . . are glass transition temperatures (unit: k) of homopolymers of monomer 1, monomer 2, monomer 3 . . . , respectively, and W1, W2, W3 . . . are copolymerization ratios of monomer 1, monomer 2 and monomer 3, respectively.

The compound (B) having an acid value of 30 to 250 mg KOH/g may be contained alone or as a mixture of two or more kinds thereof, or a photosensitive component having an acid value of less than 30 mg KOH/g or more than 250 mg KOH/g may be used in combination in addition to the compound (B) having an acid value of 30 to 250 mg KOH/g.

It is preferred that the compound (B) is a photosensitive compound having an unsaturated double bond because finer patterning can be performed using a photolithography method in which a conductive paste applied onto a substrate is exposed and developed. In this case, it is preferred that the conductive paste contains a photopolymerization initiator (D) which is decomposed by absorbing light having a short wavelength, such as an ultraviolet ray, to generate a radical, or a compound which undergoes a hydrogen extraction reaction to generate a radical. Specific examples include, but are not particularly limited to, 1,2-octanedione, 1-[4-(phenylthio)-2-(O-benzoyloxime)], generate a radical. Specific examples include, but are not particularly limited to, 1,2-octanedione, 1-[4-(phenylthio)-2-(O-benzoyloxime)], 2,4,6-trimethylbenzoyl-diphenyl-phosphine oxide, bis(2,4,6-trimethylbenzoyl)-phenyl phosphine oxide, ethanone, 1-[9-ethyl-6-2(2-methylbenzoyl)-9H-carbazole-3-yl]-1-(O-acetyloxime), benzophenone, methyl o-benzoylbenzoate, 4,4′-bis(dimethylamino)benzophenone, 4,4′-bis(diethylamino)benzophenone, 4,4′-dichlorobenzophenone, 4-benzoyl-4′-methyldiphenylketone, dibenzylketone, fluorenone, 2,2′-diethoxyacetophenone, 2,2-dimethoxy-2-phenylacetophenone, 2-hydroxy-2-methylpropiophenone, p-t-butyldichloroacetophenone, thioxanthone, 2-methylthioxanthone, 2-chlorothioxanthone, 2-isopropylthioxanthone, diethylthioxanthone, benzyl, benzyl dimethyl ketal, benzyl-β-methoxyethyl acetal, benzoin, benzoin methyl ether, benzoin butyl ether, anthraquinone, 2-t-butylanthraquinone, 2-amylanthraquinone, β-chloroanthraquinone, anthrone, benzanthrone, dibenzosuberone, methylene anthrone, 4-azidebenzalacetophenone, 2,6-bis(p-azidebenzylidene)cyclohexanone, 6-bis(p-azidebenzylidene)-4-methylcyclohexanone, 1-phenyl-1,2-butanedione-2-(o-methoxycarbonyl)oxime, 1-phenyl-propanedione-2-(o-ethoxycarbonyl)oxime, 1-phenyl-propanedione-2-(o-benzoyl)oxime, 1,3-diphenyl-propanetrione-2-(o-ethoxycarbonyl)oxime, 1-phenyl-3-ethoxy-propanetrione-2-(o-benzoyl)oxime, Michler's ketone, 2-methyl-[4-(methylthio)phenyl]-2-morpholino-1-propanone, naphthalenesulfonyl chloride, quinolinesulfonyl chloride, N-phenylthioacridone, 4,4′-azobisisobutyronitrile, diphenyl disulfide, benzothiazole disulfide, triphenylphosphine, camphor quinone, 2,4-diethylthioxanthone, isopropylthioxanthone, carbon tetrabromide, tribromophenylsulfone, benzoyl peroxide, and combinations of photo-reductive pigments such as eosin and methylene blue and reducing agents such as ascorbic acid and triethanolamine.

The added amount of the photopolymerization initiator (D) is preferably 0.05 to 30 parts by weight, more preferably 5 to 20 parts by weight based on 100 parts by weight of the compound (B) having an acid value of 30 to 250 mg KOH/g. When the added amount of the photopolymerization initiator (D) is 5 parts by weight or more based on 100 parts by weight of the compound (B), the curing density of an exposed part in particular increases so that the residual film ratio after development can be enhanced. When the added amount of the photopolymerization initiator (D) is 20 parts by weight or less based on 100 parts by weight of the compound (B), excessive absorption of light particularly by the photopolymerization initiator (D) at the upper part of a coating film can be suppressed to inhibit the conductive pattern from being reversely tapered to reduce adhesion with a base material.

To the conductive paste can be added a sensitizer along with the photopolymerization initiator (D) to improve the sensitivity and expand the range of wavelengths effective for reaction.

Specific examples of the sensitizer include 2,4-diethylthioxanthone, isopropylthioxanthone, 2,3-bis(4-diethylaminobenzal)cyclopentanone, 2,6-bis(4-dimethylaminobenzal)cyclohexanone, 2,6-bis(4-dimethylaminobenzal)-4-methylcyclohexanone, Michler's ketone, 4,4-bis(diethylamino)benzophenone, 4,4-bis(dimethylamino)chalcone, 4,4-bis(diethylamino)chalcone, p-dimethylaminocinnamylideneindanone, p-dimethylaminobenzylideneindanone, 2-(p-dimethylaminophenylvinylene)isonaphthothiazole, 1,3-bis(4-dimethylaminophenylvinylene)isonaphthothiazole, 1,3-bis(4-dimethylaminobenzal)acetone, 1,3-carbonylbis(4-diethylaminobenzal)acetone, 3,3-carbonylbis(7-diethylaminocoumarin), N-phenyl-N-ethylethanolamine, N-phenylethanolamine, N-tolyldiethanolamine, isoamyl dimethylaminobenzoate, isoamyl diethylaminobenzoate, 3-phenyl-5-benzoylthiotetrazole and 1-phenyl-5-ethoxycarbonylthiotetrazole. One or more of these compounds can be used. When the sensitizer is added to the conductive paste, the added amount thereof is normally preferably 0.05 to 10 parts by weight, more preferably 0.1 to 10 parts by weight based on 100 parts by weight of the compound (B) having an acid value of 30 to 250 mg KOH/g. When the added amount of the sensitizer is 0.1 part by weight or more based on 100 parts by weight of the compound (B), an effect of improving the light sensitivity is easily exhibited sufficiently, and when the added amount is 10 parts by weight or less based on 100 parts by weight of the compound (B), a situation can be inhibited in which light is excessively absorbed particularly at the upper part of a coating film so that the conductive pattern is reversely tapered to reduce adhesion with a base material.

The conductive filler (C) contained in the conductive paste preferably includes at least one of Ag, Au, Cu, Pt, Pb, Sn, Ni, Al, W, Mo, ruthenium oxide, Cr, Ti and indium, and these conductive fillers can be used alone, or as an alloy or a mixed powder. Conductive particles obtained by coating insulating particles or conductive particles with the above-mentioned component can be similarly used. Particularly, Ag, Cu and Au are preferred from the viewpoint of conductivity, and Ag is preferred from the viewpoint of costs and stability.

The volume average particle size of the conductive filler (C) is preferably 0.1 to 10 μm, more preferably 0.5 to 6 μm. When the volume average particle size is 0.5 μm or more, the probability of contact between conductive fillers is improved, the specific resistivity and breakage probability of the conductive pattern prepared can be reduced, and ultraviolet rays during exposure can be smoothly transmitted through the film, so that fine patterning becomes easy. When the volume average particle size is 6 μm or less, surface smoothness, pattern accuracy and dimensional accuracy of a circuit pattern after printing are improved. The volume average particle size can be determined by the Coulter counter method.

The added amount of the conductive filler (C) is preferably 70 to 95% by weight, more preferably 80 to 90% by weight based on the total solid content in the conductive paste. When the added amount of the conductive filler (C) is 80% by weight or more, the probability of contact between conductive fillers particularly in setting shrinkage during curing is improved, the specific resistivity and breakage probability of the conductive pattern prepared can be reduced. When the added amount of the conductive filler (C) is 90% by weight or less, ultraviolet rays particularly during exposure can be smoothly transmitted through the film so that fine patterning becomes easy.

The conductive paste may contain a solvent. Examples of the solvent include N,N-dimethylacetamide, N,N-dimethylformamide, N-methyl-2-pyrrolidone, dimethyl imidazolidinone, dimethyl sulfoxide, diethylene glycol monoethyl ether, diethylene glycol monoethyl ether acetate, γ-butyrolactone, ethyl lactate, 1-methoxy-2-propanol, 1-ethoxy-2-propanol, ethylene glycol mono-n-propyl ether, diacetone alcohol, tetrahydrofurfuryl alcohol, propylene glycol monomethyl ether acetate. One solvent may be used, or two or more solvents may be mixed and used. The solvent may be added to adjust the viscosity after preparation of the paste.

The conductive paste may contain additives such as a plasticizer, a leveling agent, a surfactant, a silane coupling agent, an antifoaming agent and a pigment as long as its desired characteristics are not impaired.

Specific examples of the plasticizer include dibutyl phthalate, dioctyl phthalate, polyethylene glycol and glycerin. Specific examples of the leveling agent include special vinyl-based polymers and special acryl-based polymers.

Examples of the silane coupling agent include methyltrimethoxysilane, dimethyldiethoxysilane, phenyltriethoxysilane, hexamethyldisilazane, 3-methacryloxypropyltrimethoxysilane, 3-glycidoxypropyltrimethoxysilane and vinyltrimethoxysilane.

The conductive paste is prepared using a disperser, a kneader or the like. Specific examples thereof include, but are not limited to, a three-roll roller, a ball mill and a planetary ball mill.

A method of producing a conductive pattern using the conductive paste will now be described. To prepare a conductive pattern, the paste is applied onto a substrate and dried by heating the paste to volatilize a solvent as necessary when the conductive pastes contains a solvent. Thereafter, a desired pattern is formed on the substrate by passing through a development step with the paste exposed via a pattern forming mask. Then, the pattern is cured at a temperature of 100° C. or more and 300° C. or less to prepare a conductive pattern.

Examples of the substrate include, but are not limited to, PET films, polyimide films, polyester films, aramid films, epoxy resin substrates, polyether imide resin substrates, polyether ketone resin substrates, polysulfone-based resin substrates, glass substrates, silicon wafers, alumina substrates, aluminum nitride substrates, silicon carbide substrates, decorated layer-formed substrates and insulating layer-formed substrates.

Examples of the method of applying the conductive paste include spin coating, spray coating, roll coating, screen printing, blade coaters, die coaters, calender coaters, meniscus coaters and bar coaters. The coating film thickness varies depending on a coating method, a solid concentration of the composition, a viscosity and the like, but the paste is normally applied such that the film thickness after drying is 0.1 to 50 μm.

Next, a solvent is removed from the coating film applied onto the substrate as necessary when the conductive paste contains a solvent. Examples of the method of removing the solvent include heating/drying by an oven, a hot plate, an infrared ray or the like and vacuum drying. Preferably, heating/drying is performed at 50° C. to 180° C. for 1 minute to several hours.

The coating film after the solvent is removed as necessary is pattern-processed by a photolithography method. The light source to be used for exposure is preferably the i ray (365 nm), the h ray (405 nm) or the g ray (436 nm) of a mercury lamp.

After exposure, a desired pattern is obtained by removing an unexposed part using a developer. As a developer to be used for alkali development, an aqueous solution of a compound such as tetramethylammonium hydroxide, diethanolamine, diethylaminoethanol, sodium hydroxide, potassium hydroxide, sodium carbonate, potassium carbonate, triethylamine, diethylamine, methylamine, dimethylamine, dimethylaminoethyl acetate, dimethylaminoethanol, dimethylaminoethyl methacrylate, cyclohexylamine, ethylenediamine, hexamethylenediamine or the like is preferred. In some cases, a liquid obtained by adding to the aforementioned aqueous solution one or more of polar solvents such as N-methyl-2-pyrrolidone, N,N-dimethylformamide, N,N-dimethylacetamide, dimethyl sulfoxide and γ-butyrolactone, alcohols such as methanol, ethanol and isopropanol, esters such as ethyl acetate and propylene glycol monomethyl ether acetate, and ketones such as cyclopentanone, cyclohexanone, isobutyl ketone and methyl isobutyl ketone may be used as a developer. A liquid obtained by adding a surfactant to the above-mentioned aqueous alkali solution may also be used as a developer. As a developer to be used for organic development, a polar solvent such as N-methyl-2-pyrrolidone, N-acetyl-2-pyrrolidone, N,N-dimethylacetamide, N,N-dimethylformamide, dimethyl sulfoxide or hexamethylphosphortriamide alone, or a mixed solution with the polar solvent combined with methanol, ethanol, isopropyl alcohol, xylene, water, methyl carbitol, ethyl carbitol or the like may be used.

Development can be performed by a method in which the developer is sprayed to a coating film surface while a substrate is left at rest or rotated, or a substrate is immersed in a developer, or a substrate is immersed while an ultrasonic wave is applied thereto.

After development, a rinsing treatment with water may be performed. The rinsing treatment may be performed with an alcohol such as ethanol or isopropyl alcohol or an ester such as ethyl lactate or propylene glycol monomethyl ether acetate added to water.

Next, the paste composition film is cured to exhibit conductivity. Examples of the method of curing the paste composition film include heating/drying by an oven, an inert oven, a hot plate, an infrared ray or the like and vacuum drying. The curing temperature is preferably 100 to 300° C., more preferably 120 to 180° C. When the heating temperature is 120° C. or higher, the volume shrinkage amount can be increased, leading to a decrease in specific resistivity. The conductive paste can be used on a substrate having low heat resistance, or used in combination with a material having low heat resistance because high conductivity can be obtained by curing at a relatively low temperature of 180° C. or lower. In this way, a conductive pattern can be prepared by passing through a curing step.

### EXAMPLES

Examples of our conductive pastes and methods will be described below, but this disclosure is not limited to these examples. Materials and evaluation methods used in the examples and comparative examples are as follows.

Method of Measuring Aspect Ratio

The aspect ratios of 100 particles from a SEM or TEM image were determined, and an average value thereof was defined as an aspect ratio of composite particles (A).

Method of Evaluating Patterning Characteristics

A conductive paste was applied onto a PET film to have a dry thickness of 10 μm, dried in a drying oven at 90° C. for 5 minutes, exposed via a photomask having a light transmission pattern having nine units having different L/S values, one unit including a group of lines arranged with a fixed line-and-space (L/S), developed and cured at 130° C. for 1 hour to obtain a conductive pattern. The L/S values of the units were set to 500/500, 250/250, 100/100, 50/50, 40/40, 30/30, 25/25, 20/20 and 15/15 (each showing a line width (μm)/interval (μm)). The pattern was observed with an optical microscope to confirm a pattern which was free from residues between patterns and free from pattern peeling and had the smallest L/S value, and the smallest L/S value was defined as a development-enabling L/S.

Method of Evaluating Specific Resistivity

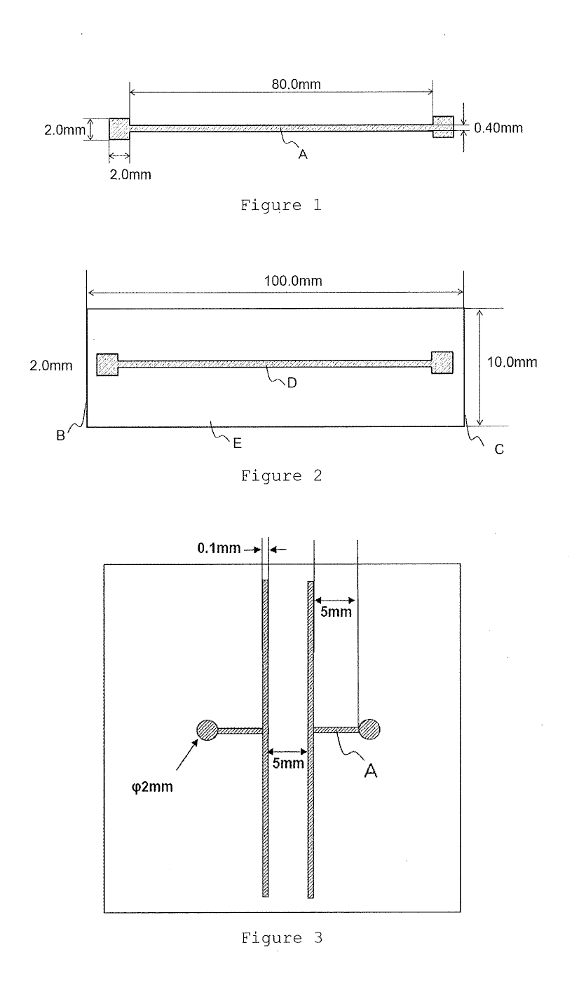

A conductive paste was applied onto a PET film to have a dry thickness of 10 μm, dried in a drying oven at 90° C. for 10 minutes, exposed via a photomask having a light transmission part A with a pattern shown in FIG. 1, developed and cured in a drying oven at 130° C. for 1 hour to obtain a specific resistivity measuring conductive pattern. The conductive pattern has a line width of 0.400 mm and a line length of 80 mm. Ends of the obtained pattern were connected through a surface resistance meter to measure a surface resistance value, and a specific resistivity was calculated by fitting the measured value in the calculation formula described below. The film thickness was measured using a probe type step profiler “SURFCOM (registered trademark) 1400” (trade name, manufactured by TOKYO SEIMITSU CO., LTD.). The film thickness was measured at randomly selected three positions, and an average value of the thicknesses at three positions was defined as a film thickness. The wavelength was 1 mm, and the scanning speed was 0.3 mm/s. For the line width, an average value of line widths at three positions obtained by observing the pattern at randomly selected three positions with an optical microscope and analyzing the image data was defined as a line width.

Specific resistivity=surface resistance value×thickness×line width/line length

Method of Evaluating Flexibility

FIG. 2 schematically shows a sample used in a flexibility test. A conductive paste was applied onto a rectangular PET film of 10 mm (length)×100 mm (width) (thickness: 40 μm) so as to have a dry thickness of 10 μm, dried in a drying oven at 90° C. for 10 minutes, and exposed while a photomask having a light transmission part A with a pattern shown in FIG. 1 was disposed such that the light transmission part was positioned at the center of the sample, and the conductive paste was developed and cured in a drying oven at 130° C. for 1 hour to obtain a conductive pattern. A resistance value was measured using a tester. Thereafter, a bending operation of bringing a sample short side B and a sample short side C into contact with each other with the sample bent to situate the conductive pattern at the inner side and the outer side alternately and returning the sample to its original state was repeated 100 times, followed by measuring a resistance value again by the tester. Rating “0” was assigned when the amount of change in resistance value was 20% or less as a result of the measurement, and cracking, peeling and line breakage etc. did not occur in the conductive pattern, and rating “x” was assigned otherwise.

Method of Evaluating Connection Reliability with ITO

A conductive paste was applied onto a transparent conductive film, in which a PET film was sputter-coated with ITO over the entire surface to have a dry thickness of 10 μm, dried in a drying oven at 90° C. for 10 minutes, exposed via a photomask having a light transmission part A with a pattern shown in FIG. 3, developed and cured in a drying oven at 130° C. for 1 hour to obtain a sample for evaluation connection reliability with ITO. The conductive pattern has a line width of 100 μm and a line interval of 5 mm, and the terminal part is in the form of a circle having a diameter of 2 mm. Terminal parts of the obtained sample were connected through a tester to measure an initial resistance, and the sample was then placed in a thermo-hygrostat bath “LU-113” (trade name, manufactured by ESPEC CORP.) at 85° C. and 85% RH for 500 hours. Thereafter, the sample was taken out, its terminal parts were connected through the tester again to measure a resistance value, a resistance change rate was calculated using the following equation, and rating “◯” was assigned when the resistance change rate was 1.3 or less while rating “x” was assigned when the resistance change rate was more than 1.3.

Resistance change rate=resistance value (after 500 hours)/initial resistance value

Materials used in the examples and comparative examples are as follows.

Particles (A) Formed by Coating the Surfaces of Inorganic Particles with an Antimony-Containing Compound

ET-300W (trade name, manufactured by ISHIHARA SANGYO KAISHA, LTD., composite particles formed by coating a core material composed of titanium oxide with antimony-doped tin oxide, aspect ratio: 1.1, volume average particle size: 0.03 to 0.06 μm)
ET-500W (trade name, manufactured by ISHIHARA SANGYO KAISHA, LTD., composite particles formed by coating a core material composed of titanium oxide with antimony-doped tin oxide, aspect ratio: 1.1, volume average particle size: 0.2 to 0.3 μm)
FT-1000 (trade name, manufactured by ISHIHARA SANGYO KAISHA, LTD., composite particles formed by coating a core material composed of titanium oxide with antimony-doped tin oxide, aspect ratio: 12.9, volume average particle size: 0.18 μm)
Passtran (registered trademark) 4410 (trade name, manufactured by MITSUI MINING & SMELTING CO., LTD., composite particles formed by coating a core material composed of barium sulfate with antimony-doped tin oxide, aspect ratio: 1.2, volume average particle size: 0.1 μm)

Compound (B) Having an Acid Value of 30 to 250 mg KOH/g

KAYARAD (registered trademark) ASP-010 (trade name, manufactured by Nippon Kayaku Co., Ltd., acryl-based copolymer having no unsaturated double bond, acid value: 46 mg KOH/g, glass transition temperature: 60° C. (measured by DSC))
Curalite (registered trademark) 2300 (trade name, manufactured by Perstorp Company, polyester-based resin, acid value: 229 mg KOH/g, glass transition temperature: 45° C. (measured by DSC))

### Synthesis Example 1

### Compound B-1 Having an Acid Value of 30 to 250 mg KOH/g

Photosensitive component obtained by addition reaction of 5 parts by weight of glycidyl methacrylate (GMA) with a copolymer of ethyl acrylate (EA)/2-ethylhexyl methacrylate (2-EHMA)/styrene (st)/acrylic acid (AA) (copolymerization ratio: 20 parts by weight/40 parts by weight/20 parts by weight/15 parts by weight).

Diethylene glycol monoethyl ether acetate (150 g) was added in a reaction vessel in a nitrogen atmosphere, and the temperature elevated to 80° C. using an oil bath. To this was added dropwise for 1 hour a mixture including ethyl acrylate (20 g), 2-ethylhexyl methacrylate (40 g), styrene (20 g), acrylic acid (15 g), 2,2′-azobisisobutyronitrile (0.8 g) and diethylene glycol monoethyl ether acetate (10 g). After completion of the dropwise addition, further a polymerization reaction was carried out for 6 hours. Thereafter, hydroquinone monomethyl ether (1 g) was added to stop the polymerization reaction. Subsequently, a mixture including glycidyl methacrylate (5 g), triethyl benzyl ammonium chloride (1 g) and diethylene glycol monoethyl ether acetate (10 g) was added dropwise for 0.5 hours. After completion of the dropwise addition, further an addition reaction was carried out for 2 hours. The obtained reaction solution was refined with methanol to remove unreacted impurities, and dried under vacuum for 24 hours to obtain a compound B-1. The obtained compound B-1 had an acid value of 103 mg KOH/g and a glass transition temperature of 21.7° C. as determined from the formula (1).

### Synthesis Example 2

### Compound B-2 Having an Acid Value of 30 to 250 mg KOH/g

Photosensitive component obtained by addition reaction of 5 parts by weight of glycidyl methacrylate (GMA) with a copolymer of ethylene oxide-modified bisphenol A diacrylate FA-324A (product name, manufactured by Hitachi Chemical Co., Ltd.)/EA/AA (copolymerization ratio: 50 parts by weight/10 parts by weight/15 parts by weight).

Diethylene glycol monoethyl ether acetate (150 g) was added in a reaction vessel in a nitrogen atmosphere, and the temperature was elevated to 80° C. using an oil bath. To this was added dropwise for 1 hour a mixture including ethylene oxide-modified bisphenol A diacrylate FA-324A (50 g), ethyl acrylate (20 g), acrylic acid (15 g), 2,2′-azobisisobutyronitrile (0.8 g) and diethylene glycol monoethyl ether acetate (10 g). After completion of the dropwise addition, further a polymerization reaction was carried out for 6 hours. Thereafter, hydroquinone monomethyl ether (1 g) was added to stop the polymerization reaction. Subsequently, a mixture including glycidyl methacrylate (5 g), triethyl benzyl ammonium chloride (1 g) and diethylene glycol monoethyl ether acetate (10 g) was added dropwise for 0.5 hours, After completion of the dropwise addition, further an addition reaction was carried out for 2 hours. The obtained reaction solution was refined with methanol to remove unreacted impurities, and dried under vacuum for 24 hours to obtain a compound B-2. The obtained compound B-2 had an acid value of 96 mg KOH/g and a glass transition temperature of 19.9° C. as determined from the formula (1).

### Synthesis 3

### Compound Obtained by Addition Reaction of 5 Parts by Weight of Glycidyl Methacrylate (GMA) with a Copolymer of Epoxy Ester 3000A (Manufactured by KYOEISHA CHEMICAL Co., LTD., Molecular Weight: 476.7, Having a Bisphenol A Backbone)/2-Ethylhexyl Methacrylate (2-EHMA)/Styrene (St)/Acrylic Acid (AA) (Copolymerization Ratio: 20 Parts by Weight/40 Parts by Weight/20 Parts by Weight/15 Parts by Weight)

Diethylene glycol monoethyl ether acetate (150 g) was added in a reaction vessel in a nitrogen atmosphere, and the temperature elevated to 80° C. using an oil bath. To this was added dropwise for 1 hour a mixture including epoxy ester 3000A (20 g), 2-ethylhexyl methacrylate (40 g), styrene (20 g), acrylic acid (15 g), 2,2′-azobisisobutyronitrile (0.8 g) and diethylene glycol monoethyl ether acetate (10 g). After completion of the dropwise addition, further a polymerization reaction was carried out for 6 hours. Thereafter, hydroquinone monomethyl ether (1 g) was added to stop the polymerization reaction. Subsequently, a mixture including glycidyl methacrylate (5 g), triethyl benzyl ammonium chloride (1 g) and diethylene glycol monoethyl ether acetate (10 g) was added dropwise for 0.5 hours. After completion of the dropwise addition, further an addition reaction was carried out for 2 hours. The obtained reaction solution was refined with methanol to remove unreacted impurities, and dried under vacuum for 24 hours to obtain a compound B-3. The obtained compound B-3 had an acid value of 98 mg KOH/g and a glass transition temperature of 43.2° C. as obtained from DSC measurement.

### Synthesis 4

### Compound Obtained by Addition Reaction of 5 Parts by Weight of Glycidyl Methacrylate (GMA) with a Copolymer of Epoxy Ester 70PA (Manufactured by KYOEISHA CHEMICAL Co., LTD., Molecular Weight: 332.4, Aliphatic Chain-Type Epoxy Acrylate)/2-Ethylhexyl Methacrylate (2-EHMA)/Styrene (St)/Acrylic Acid (AA) (Copolymerization Ratio: 20 Parts by Weight/40 Parts by Weight/20 Parts by Weight/15 Parts by Weight)

Diethylene glycol monoethyl ether acetate (150 g) was added in a reaction vessel in a nitrogen atmosphere, and the temperature elevated to 80° C. using an oil bath. To this was added dropwise for 1 hour a mixture including epoxy ester 70PA (20 g), 2-ethylhexyl methacrylate (40 g), styrene (20 g), acrylic acid (15 g), 2,2′-azobisisobutyronitrile (0.8 g) and diethylene glycol monoethyl ether acetate (10 g). After completion of the dropwise addition, further a polymerization reaction was carried out for 6 hours. Thereafter, hydroquinone monomethyl ether (1 g) was added to stop the polymerization reaction. Subsequently, a mixture including glycidyl methacrylate (5 g), triethyl benzyl ammonium chloride (1 g) and diethylene glycol monoethyl ether acetate (10 g) was added dropwise for 0.5 hours. After completion of the dropwise addition, further an addition reaction was carried out for 2 hours. The obtained reaction solution was refined with methanol to remove unreacted impurities, and dried under vacuum for 24 hours to obtain a compound B-4. The obtained compound B-4 had an acid value of 96 mg KOH/g and a glass transition temperature of 23.5° C. as obtained from DSC measurement.

### Synthesis 5

epoxy ester 3000A (manufactured by KYOEISHA CHEMICAL Co., LTD., molecular weight: 476.7, having a bisphenol A backbone) (200 g), diethylene glycol monoethyl ether acetate (500 g) as a reaction catalyst, 2-methylhydroquinone (0.5 g) as a thermal polymerization inhibitor and dihydroxypropionic acid (75 g) as a diol compound having a carboxyl group (molecular weight: 106.1) were added in a reaction vessel, and the temperature was elevated to 45° C. To this solution was added dropwise hexamethylenediisocyanate (molecular weight: 168.2) (84.1 g) gradually so that the reaction temperature did not exceed 50° C. After the dropwise addition, the temperature was elevated to 80° C., and the mixture reacted for 6 hours until the absorption around 2250 cm⁻¹ was confirmed to disappear by the infrared absorption spectrum measurement method. To this solution was added 165 g of glycidyl methacrylate (molecular weight 142.2) in the molecule, the temperature was then elevated to 95° C., and the mixture reacted for 6 hours to obtain a compound B-5. A 51.2 wt % resin solution of the obtained compound B-5 was obtained. The obtained compound B-5 had an acid value of 89 mg KOH/g and a glass transition temperature of 27.2° C. as obtained from DSC measurement.

Conductive Filler (C)

A filler having the material and volume average particle size described in Table 1 was used. The volume average particle size was determined by the following method.

Photopolymerization Initiator (D)

IRGACURE (registered trademark) 369 (trade name, manufactured by Ciba Japan K.K.)

Measurement of Volume Average Particle Size

The volume average particle size of the conductive filler (C) was measured using a dynamic light scattering particle size distribution meter manufactured by HORIBA, Ltd.
Monomer: Light Acrylate BP-4EA (manufactured by KYOEISHA CHEMICAL Co., Ltd.)
Solvent: diethylene glycol monoethyl ether acetate (manufactured by Tokyo Chemical Industry Co., Ltd.)
Antimony-containing compound containing no inorganic particles and conductive tin oxide particles
   SN-100P (trade name, manufactured by ISHIHARA SANGYO KAISHA, LTD.)
   SN-10P (trade name, manufactured by ISHIHARA SANGYO KAISHA, LTD.)
   T-1 (trade name, manufactured by Mitsubishi Materials Electronic Chemicals Co., Ltd.)

### Example 1

A compound B-1 (10.0 g), a photopolymerization initiator IRGACURE (registered trademark) 369 (manufactured by Ciba Japan K.K.) (0.50 g) and diethylene glycol monoethyl ether acetate (5.0 g) were added in a 100 mL clean bottle, and mixed by “Awatori Rentaro” (registered trademark; trade name, ARE-310, manufactured by THINKY CORPORATION) to obtain a resin solution (15.5 g) (solid content: 67.7% by weight).

The obtained resin solution (10.7 g), Ag particles having an average particle size of 2 μm (50.0 g) were mixed together, and ET-300W (manufactured by ISHIHARA SANGYO KAISHA, LTD.) (0.87 g) were mixed together, and the mixture kneaded using a three-roll roller “EXAKT M-50” (trade name, manufactured by EXAKT Company) to obtain 61.6 g of a conductive paste.

The obtained paste was applied onto a PET film having a film thickness of 100 μm by screen printing, and dried in a drying oven at 90° C. for 10 minutes. Thereafter, the paste was exposed over the entire line at an exposure amount of 200 mJ/cm² (in terms of a wavelength of 365 nm) using exposure equipment “PEM-6M” (trade name, manufactured by UNION OPTICAL CO., LTD.), subjected to immersion development with a 0.25% Na₂CO₃ solution for 50 seconds, rinsed with ultrapure water, and then cured in a drying oven at 140° C. for 30 minutes. The pattern-processed conductive pattern had a film thickness of 10 μm. The line-and-space (L/S) pattern of the conductive pattern was observed with an optical microscope to confirm that the conductive pattern was satisfactorily pattern-processed with no residue between patterns and no pattern peeling when the L/S was 20/20 μm or less. The specific resistivity of the conductive pattern was measured to be 6.7×10⁻⁵ Ωcm. For flexibility, cracking and line breakage did not occur, and good results were obtained. For evaluation of connection reliability with ITO, the initial resistance was 38.4Ω, the resistance after 500 hours under an environment of 85° C. and 85% RH was 39.4Ω, and therefore the change rate was 1.03.

### Examples 2 to 11

A conductive paste with the composition shown in Table 1 was produced in the same manner as in Example 1. Evaluation results are shown in Table 2.

### Comparative Examples 1 to 3

A conductive paste with the composition shown in Table 1 was produced in the same manner as in Example 1. Evaluation results are shown in Table 2.

TABLE 1

| | Particles (A) formed by coating the | | | | | |
|---|---|---|---|---|---|---|
| | surfaces of inorganic particles with an | | | Photopolymerization | | |
| | antimony-containing compound | | | initiator (C) | | Conductive filler (D) |
| | | Added amount (% by | | | Added amount (parts | Added amount (% by |
| | | weight) based on 100 | Compound | | by weight) based on | weight) based on 100 |
| | | parts by weight of | (B) | | 100 parts by weight of | parts by weight of |
| | Type | solid content in paste | Type | Type | compound (B) | solid content in paste |
| Example 1 | ET-300W | 1.5 | B-1 | IRGACURE | 5 | 86 |
| | | | | 369 | | |
| Example 2 | ET-500W | 1.5 | B-1 | IRGACURE | 5 | 86 |
| | | | | 369 | | |
| Example 3 | FT-1000 | 1.5 | B-1 | IRGACURE | 5 | 86 |
| | | | | 369 | | |
| Example 4 | Passtran | 1.5 | B-1 | IRGACURE | 5 | 86 |
| | 4410 | | | 369 | | |
| Example 5 | FT-1000 | 0.5 | B-1 | IRGACURE | 5 | 86 |
| | | | | 369 | | |
| Example 6 | FT-1000 | 1.5 | B-2 | IRGACURE | 5 | 86 |
| | | | | 369 | | |
| Example 7 | FT-1000 | 1.5 | B-3 | IRGACURE | 5 | 86 |
| | | | | 369 | | |
| Example 8 | FT-1000 | 1.5 | B-4 | IRGACURE | 5 | 86 |
| | | | | 369 | | |
| Example 9 | FT-1000 | 1.5 | B-5 | IRGACURE | 5 | 86 |
| | | | | 369 | | |
| Example 10 | ET-500W | 1.5 | KAYARAD | — | — | 86 |
| | | | ASP-010 | | | |
| Example 11 | ET-500W | 1.5 | Curalite | — | — | 86 |
| | | | 2300 | | | |
| Comparative | SN-100P | 1.5 | B-1 | IRGACURE | 5 | 86 |
| Example 1 | | | | 369 | | |
| Comparative | FS-10P | 1.5 | B-2 | IRGACURE | 5 | 86 |
| Example 2 | | | | 369 | | |
| Comparative | T-1 | 1.5 | B-2 | IRGACURE | 5 | 86 |
| Example 3 | | | | 369 | | |

| | | | Monomer | | Solvent | |
|---|---|---|---|---|---|---|
| | Conductive filler (D) | | | Added amount (parts | | Added amount (parts |
| | | Average | | by weight) based on | | by weight) based on |
| | | particle | | 100 parts by weight of | | 100 parts by weight of |
| | Type | size (μm) | Type | compound (B) | Type | compound (B) |
| Example 1 | Ag | 2.0 | BP-4EA | 20 | Diethylene glycol | 50 |
| | | | | | monoethyl ether | |
| | | | | | acetate | |
| Example 2 | Ag | 2.0 | BP-4EA | 20 | Diethylene glycol | 50 |
| | | | | | monoethyl ether | |
| | | | | | acetate | |
| Example 3 | Ag | 2.0 | BP-4EA | 20 | Diethylene glycol | 50 |
| | | | | | monoethyl ether | |
| | | | | | acetate | |
| Example 4 | Ag | 2.0 | BP-4EA | 20 | Diethylene glycol | 50 |
| | | | | | monoethyl ether | |
| | | | | | acetate | |
| Example 5 | Ag | 2.0 | BP-4EA | 20 | Diethylene glycol | 50 |
| | | | | | monoethyl ether | |
| | | | | | acetate | |
| Example 6 | Ag | 2.0 | — | — | Diethylene glycol | 50 |
| | | | | | monoethyl ether | |
| | | | | | acetate | |
| Example 7 | Ag | 2.0 | BP-4EA | 20 | Diethylene glycol | 50 |
| | | | | | monoethyl ether | |
| | | | | | acetate | |
| Example 8 | Ag | 2.0 | BP-4EA | 20 | Diethylene glycol | 50 |
| | | | | | monoethyl ether | |
| | | | | | acetate | |
| Example 9 | Ag | 2.0 | BP-4EA | 20 | Diethylene glycol | 50 |
| | | | | | monoethyl ether | |
| | | | | | acetate | |
| Example 10 | Ag | 2.0 | — | — | Diethylene glycol | 50 |
| | | | | | monoethyl ether | |
| | | | | | acetate | |
| Example 11 | Ag | 2.0 | — | — | Diethylene glycol | 50 |
| | | | | | monoethyl ether | |
| | | | | | acetate | |
| Comparative | Ag | 2.0 | BP-4EA | 20 | Diethylene glycol | 50 |
| Example 1 | | | | | monoethyl ether | |
| | | | | | acetate | |
| Comparative | Ag | 2.0 | BP-4EA | 20 | Diethylene glycol | 50 |
| Example 2 | | | | | monoethyl ether | |
| | | | | | acetate | |
| Comparative | Ag | 2.0 | BP-4EA | 20 | Diethylene glycol | 50 |
| Example 3 | | | | | monoethyl ether | |
| | | | | | acetate | |

TABLE 2

| | | | Characteristics of conductive pattern | | | | | | |
|---|---|---|---|---|---|---|---|---|---|
| | | | | | | Connection reliability with ITO | | | |
| | | | | | | | Resistance | | |
| | Preparation conditions | | | Specific | | Initial | value (Ω) | | |
| | | Curing | Development-enabling | resistivity | | resistance | after 500 | Resistance | |
| | Substrate | conditions | L/S (μm) | (Ωcm) | Flexibility | value (Ω) | hours | change rate | Assessment |
| Example 1 | PET film | 140° C. × 30 min | 20/20 | 6.7 × 10⁻⁵ | ∘ | 38.4 | 39.4 | 1.21 | ∘ |
| Example 2 | PET film | 140° C. × 30 min | 20/20 | 7.4. × 10⁻⁵ | ∘ | 37.7 | 39.5 | 1.25 | ∘ |
| Example 3 | PET film | 140° C. × 30 min | 20/20 | 6.6 × 10⁻⁵ | ∘ | 38.2 | 38.8 | 1.03 | ∘ |
| Example 4 | PET film | 140° C. × 30 min | 20/20 | 7.1 × 10⁻⁵ | ∘ | 39.9 | 41.2 | 1.26 | ∘ |
| Example 5 | PET film | 140° C. × 30 min | 20/20 | 5.6 × 10⁻⁵ | ∘ | 38.2 | 38.9 | 1.08 | ∘ |
| Example 6 | PET film | 140° C. × 30 min | 20/20 | 6.5 × 10⁻⁵ | ∘ | 38.2 | 39.6 | 1.03 | ∘ |
| Example 7 | PET film | 140° C. × 30 min | 20/20 | 5.2 × 10⁻⁵ | ∘ | 38.2 | 39.1 | 1.02 | ∘ |
| Example 8 | PET film | 140° C. × 30 min | 20/20 | 4.9 × 10⁻⁵ | ∘ | 38.1 | 38.7 | 1.02 | ∘ |
| Example 9 | PET film | 140° C. × 30 min | 20/20 | 5.5 × 10⁻⁵ | ∘ | 38.2 | 38.9 | 1.02 | ∘ |
| Example 10 | PET film | 140° C. × 30 min | — | 6.1 × 10⁻⁵ | ∘ | 38.8 | 49.7 | 1.28 | ∘ |
| Example 11 | PET film | 140° C. × 30 min | — | 5.7 × 10⁻⁵ | ∘ | 39.3 | 48.7 | 1.24 | ∘ |
| Comparative | PET film | 140° C. × 30 min | Generation of residues | 6.4. × 10⁻⁵ | ∘ | 40.2 | 71.9 | 1.79 | x |
| Example 1 | | | | | | | | | |
| Comparative | PET film | 140° C. × 30 min | Generation of residues | 7.4. × 10⁻⁵ | ∘ | 39.2 | 89.4 | 2.28 | x |
| Example 2 | | | | | | | | | |
| Comparative | PET film | 140° C. × 30 min | Generation of residues | 6.4 × 10⁻⁵ | ∘ | 38.8 | 83.3 | 2.15 | x |
| Example 3 | | | | | | | | | |

All the conductive pastes of Examples 1 to 11 were excellent in patterning characteristics and connection reliability, but all the conductive pastes of Comparative Examples 1 to 3 were poor in patterning characteristics with residues generated even in a pattern having a line/space of 500 μm/500 μm, and had a high resistance change rate and thus poor connection reliability.

1.-12. (canceled)

13. A conductive paste comprising: composite particles (A) formed by coating a surface of a core material composed of an inorganic material with an antimony-containing compound; a compound (B) having an acid value of 30 to 250 mg KOH/g; and a conductive filler (C).

14. The conductive paste according to claim 13, wherein the compound (B) has an unsaturated double bond.

15. The conductive paste according to claim 13, further comprising a photopolymerization initiator (D).

16. The conductive paste according to claim 13, wherein the antimony-containing compound is antimony-doped tin oxide.

17. The conductive paste according to claim 13, wherein the core material of the composite particles (A) comprises a metal compound selected from the group consisting of titanium oxide, barium sulfate, aluminum oxide, silicon dioxide, iron oxide, nickel oxide, copper oxide, carbon, gold, platinum, tungsten and titanium.

18. The conductive paste according to claim 13, wherein the core material of the composite particles (A) comprises a metal compound selected from the group consisting of titanium oxide, barium sulfate, silicon dioxide and carbon.

19. The conductive paste according to claim 13, wherein the composite particles (A) have an aspect ratio of 1.5 to 50.

20. The conductive paste according to claim 13, wherein the composite particles (A) have an aspect ratio of 10 to 50.

21. The conductive paste according to claim 13, wherein the conductive paste contains 0.5 to 2% by weight of the composite particles (A) and 70 to 90% by weight of the conductive filler (C).

22. The conductive paste according to claim 13, wherein the compound (B) has a glass transition temperature of −10 to 60° C.

23. A method of producing a conductive pattern, wherein the conductive paste according to claim 13 is applied onto a substrate, exposed, developed, and then cured at a temperature of 100° C. or more and 300° C. or less.

24. A touch panel comprising peripheral wiring in which the conductive pattern according to claim 23 and ITO are in contact with each other.

25. The conductive paste according to claim 14, further comprising a photopolymerization initiator (D).

26. The conductive paste according to claim 14, wherein the antimony-containing compound is antimony-doped tin oxide.

27. The conductive paste according to claim 15, wherein the antimony-containing compound is antimony-doped tin oxide.

28. The conductive paste according to claim 14, wherein the core material of the composite particles (A) comprises a metal compound selected from the group consisting of titanium oxide, barium sulfate, aluminum oxide, silicon dioxide, iron oxide, nickel oxide, copper oxide, carbon, gold, platinum, tungsten and titanium.

29. The conductive paste according to claim 15, wherein the core material of the composite particles (A) comprises a metal compound selected from the group consisting of titanium oxide, barium sulfate, aluminum oxide, silicon dioxide, iron oxide, nickel oxide, copper oxide, carbon, gold, platinum, tungsten and titanium.

30. The conductive paste according to claim 16, wherein the core material of the composite particles (A) comprises a metal compound selected from the group consisting of titanium oxide, barium sulfate, aluminum oxide, silicon dioxide, iron oxide, nickel oxide, copper oxide, carbon, gold, platinum, tungsten and titanium.

31. The conductive paste according to claim 14, wherein the core material of the composite particles (A) comprises a metal compound selected from the group consisting of titanium oxide, barium sulfate, silicon dioxide and carbon.

32. The conductive paste according to claim 15, wherein the core material of the composite particles (A) comprises a metal compound selected from the group consisting of titanium oxide, barium sulfate, silicon dioxide and carbon.
